(19) United States
(12) Patent Application Publication
(10) Pub. No.: US 2009/0106624 A1
(43) Pub. Date: Apr. 23, 2009

(54) ERROR CORRECTION METHOD

(76) Inventors: Hiroaki Kondo, Osaka (JP); Shiro Shimizu, Osaka (JP)

Correspondence Address: WENDEROTH, LIND & PONACK L.L.P., 1030 15th Street, N.W., Suite 400 East, Washington, DC, 20005-1503, US

(21) Appl. No.: 12/065,233

(22) PCT Filed: Aug. 31, 2006
(86) PCT No.: PCT/JP2006/317275

§ 371 Date: Feb. 28, 2008

(30) Foreign Application Priority Data
Sep. 1, 2005 (JP) 2005-254013

(51) Int. Cl. H03M 13/29; G06F 11/08

(52) U.S. Cl. 714/755; 714/E11.03

(57) ABSTRACT

According to an error correction method of the present invention, in the case of decoding a code word (104) which is doubly encoded by adding first and second inspection data (102,103) having minimum distances d1 and d2 from other data, respectively, a position Ex of an erasure symbol X for which an error was detected using the second inspection data (103) but the error could not be corrected is regarded as an erasure position, and a pseudo erasure symbol Y for which an error was detected using the second inspection data (103) and the error was corrected is regarded as being erroneously corrected and a position Ey of this pseudo erasure symbol is also regarded as an erasure position in first-time decoding, and erasure corrections for up to (d1−d) pieces of symbols are performed at one time using the first inspection data (102) when performing second-time decoding using these position information Ex and Ey. Thereby, an error correction method having a minimum number of times of decoding can be realized, and the error correction capability can be enhanced.

### TECHNICAL FIELD

The present invention relates to a preferable error correction method to be used when performing decoding to a code word that is obtained by doubly encoding a digital signal.

### BACKGROUND ART

In recording/reproduction or transmission of digital audio data comprising 0 and 1, there are many cases where data different from information data to be a target of encoding/decoding, which are called inspection data, are added to data errors which occur when performing the recording/reproduction or during the transmission, and error detection and error correction are performed using the inspection data.

As a method for adding this inspection data, a Reed-Solomon code is well used. Especially, data which is doubly encoded by the Reed-Solomon code has a high data correction capability against random errors although the data can be easily decoded, and therefore, it is well used for recording/reproduction of digital audio disks.

A description will be given of a compact disk recording method in which coding is doubly performed by the Reed-Solomon code.

FIG. 1 shows an example of double coding by the Reed-Solomon code.

With reference to FIG. 1, W0 to W23 denote information data 101, Q0 to Q3 denote first inspection data 102, and P0 to P3 denote second inspection data 103, respectively. A C1 frame 104 is a data sequence that is continuous in a horizontal direction, and a C2 frame 105 is a data sequence which is obtained by successively selecting data that exist at constant intervals in a obliquely downward right direction viewed from the position of W0.

Double coding by the Reed-Solomon code is performed as follows. Initially, as shown by dotted lines in FIG. 1, the first inspection data 102 of 4 symbols (Q0 to Q3) are added to the information data 101 of 24 symbols (W0 to W23) in the C2 frame 105 such that a minimum distance d1 with respect to another frame becomes 5. The data of 28 symbols in the C2 frame 105 are subjected to interleaving having a delay of 4 to rearrange the data in a transverse line (horizontal direction), resulting in the C1 frame 104 which is a data sequence continuous in the horizontal direction. Then, the second inspection data 103 of 4 symbols (P0 to P3) are added to the data of 28 symbols in the C1 frame 104 such that a minimum distance d2 with respect to another frame becomes 5.

Thus obtained coded data of 32 symbols comprising the information data 101 of 24 symbols, the first inspection data 102 of 4 symbols, and the second inspection data 103 of 4 symbols are recorded in a compact disk.

On the other hand, decoding of the data recorded in the compact disk is performed as follows. Initially, C1 decoding is performed to the data of 32 symbols in the C1 frame 104. In this C1 decoding, error detection and error correction are performed to the data of 32 symbols in the C1 frame 104 with using the second inspection data 103 of P0 to P3. Then, deinterleaving is performed to the data of 28 symbols in the C1 frame 104 which was subjected to the C1 decoding, thereby to rearrange the C1 frame 104 like the C2 frame 105, followed by C2 decoding. In the C2 decoding, error detection and error correction are performed to the data of 28 symbols in the C2 frame 105 with using the first inspection data 102 of Q0 to Q3. Thereby, correctly decoded information data 101 of 24 symbols W0 to W23 are obtained.

As described above, in the decoding for the data recorded in the compact disk, since the C1 decoding adopts the Reed-Solomon code having a code length of 32, the number of inspection data being 4, and a minimum distance from other data being 5, it is possible to execute error detection for up to 4 errors and error correction for up to 2 errors whose error positions are unclear.

Further, since the C2 decoding adopts the Reed-Solomon code having a code length of 28, the number of inspection data being 4, and a minimum distance from other data being 5, it is possible to execute error correction for up to m pieces of errors whose error positions are unclear (these errors whose error positions are unclear are called “S”) and erasure correction for up to x pieces of erasure symbols X, which satisfy a relational formula of 2m+x≦4 (m, x are integers not less than 0), by recording position information Ex of all the symbols in the frame (these symbols are referred to as erasure symbols X) for which error detection was performed but error correction could not be performed in the C1 decoding.

For example, when performing error correction in the state where three erasure symbols exist in the C2 decoding, the number of symbols that are correctable using the position information Ex is three at maximum. That is, it is possible to perform erasure correction for three symbols, or to perform erasure correction for two symbols and error correction for one error S whose error position is unclear, with ignoring one erasure symbol.

At this time, however, if there is a part where erroneous correction was performed in the C1 decoding, there may occur a problem that the portion cannot be corrected in the C2 decoding or erroneous correction occurs and thereby the information data cannot be correctly decoded. However, actually, there are many cases where the information data can be correctly decoded without being affected by the erroneous correction in the C1 decoding, by recording the position information Ey of the symbols in the frame which were corrected in the C1 decoding (these symbols are referred to as pseudo erasure symbols Y) with assumption that the pseudo erasure symbols Y are symbols that were erroneously corrected in the C1 decoding, and performing erasure correction in the C2 decoding using the position information Ey of the symbols Y and the above-described position information Ex.

A technique for performing such error correction is disclosed in Patent Document 1. Hereinafter, the error correction method disclosed in Patent Document 1 will be described with reference to FIG. 5.

Decoding of coded data recorded on a compact disk is started (step S1), and initially C1 decoding is carried out (step S2).

Then, first-time C2 decoding is performed to the C1-decoded data without considering the position information Ex and Ey of the erasure symbols X and the pseudo erasure symbols Y which were obtained in the C1 decoding, thereby performing error detection for up to four errors and correction for up to two errors S whose error positions are unclear (step S4).

Then, the number of detected errors is counted (step S5), and the subsequent processing is performed according to the number of errors (step S6).

When the number of errors counted in the first-time C2 decoding is two or less, the processing is ended (step S7).

In other cases, conditional branching is performed according the number of erasure symbols X and the number of pseudo erasure symbols Y which are counted in step 3, and the subsequent processing is carried out (step S8).

When the sum of the number of erasure symbols X and the number of pseudo erasure symbols Y is 5 or more, these symbols are regarded as uncorrectable and the processing is ended (step S9).

When the sum of the number of erasure symbols X and the number of pseudo erasure symbols Y is 2 or less, second-time C2 decoding, i.e., error correction for up to one error S whose error position is unclear and erasure correction for up to two symbols are performed (step S10), and the processing is ended (step S11).

When the sum of the number of erasure symbols X and the number of pseudo erasure symbols Y is 4 or less, second-time C2 decoding, i.e., erasure correction for up to four symbols, is performed (step S12), and the processing is completed (step S13).

As described above, when performing the second-time C2 decoding, erasure correction is carried out using the position information Ex of the erasure symbols X and the position information Ey of the pseudo erasure symbols Y.

Patent Document 1: Japanese Published Patent Application No. Sho. 60-95640

### DISCLOSURE OF THE INVENTION

### Problems to be Solved by the Invention

In the above-described conventional error correction method, however, error detection and error correction must be performed twice in only the C2 decoding to perform erasure correction, resulting in poor processing efficiency.

Further, since the processing must be performed with conditional branching according to the number of errors counted in the first-time C2 decoding, there occurs a new problem that the process such as conditional branching is complicated.

The present invention has for its object to provide an error correction method which can enhance the error correction capability by simple processing when decoding a code word which is obtained by doubly encoding a digital signal.

### Measures to Solve the Problems

In order to solve the above-described problems, according to Claim 1 of the present invention, there is provided an error correction method for performing error detection and error correction to a code word during decoding, which code word is obtained by performing double encoding that comprises producing first correction frames each comprising plural pieces of information data and first inspection data having a minimum distance of d1 (d1: an integer not less than 2) and added to the plural pieces of information data, and producing plural second correction frames each comprising a data sequence comprising symbols that are selected from the respective first correction frames existing in a data assembly comprising said plural first correction frames and second inspection data having a minimum distance of d2 (d2: an integer not less than 2) and added to the data sequence, which error correction method includes a first error detection/correction step of performing error detection and correction for the second correction frames with using the second inspection data, a flag generation step of generating a flag Ex for each of the second correction frames for which error detection was performed but error correction could not be performed, and generating a flag Ey for each of the second correction frames for which error detection was performed and error correction was performed, according to the results of the error detection and correction performed in the first error detection/correction step; and a second error detection/correction step of performing erasure correction for up to (d1−1) pieces of symbols at one time with using the positions of the flags Ex and Ey as erasure positions, when performing error detection and correction using the first inspection data to the first correction frames included in the data assembly which are obtained by performing error detection and correction to the second correction frames with using the second inspection data.

Further, according to Claim 2 of the present invention, in the error correction method defined in Claim 1, the second error detection/correction step comprises performing erasure correction for up to n pieces of symbols and error correction for up to m pieces of errors whose error positions are unclear, which satisfy a relational formula of n+2m≦d1−1 (n, m: integers not less than 0), at one time with using the positions of the flags Ex and Ey as erasure positions, when performing error detection and correction using the first inspection data to the first correction frames in the data assembly which are obtained by performing error detection and correction to the second correction frames with using the second inspection data.

Further, according to Claim 3 of the present invention, in the error correction method defined in Claim 2, the second error detection/correction step includes selecting whether the position of the flag Ey is to be used as an erasure position or not.

Further, according to Claim 4 of the present invention, in the error correction method defined in Claim 3, the second error detection/correction step includes performing erasure correction using the flags Ex and Ey when x≧z (z: an arbitrary integer not less than 0) while performing erasure correction using only the flags Ex when x<z, assuming that the number of the flags Ex in the first correction frames is x.

### Effects of the Invention

According to the error correction method of the present invention, when decoding a code word which is obtained by performing double decoding which comprises adding first and second inspection data respectively having minimum distances d1 and d2 from other data, the first-time decoding is performed regarding a position Ex of an erasure symbol X for which error detection was performed using the second inspection data but error correction could not be performed as an erasure position, and also regarding a pseudo erasure symbol Y for which error detection was performed using the second inspection data and error correction was also performed as being erroneously corrected, thereby to regard the position Ey of this pseudo erasure symbol as an erasure position, and the second-time decoding using these position information Ex and Ey is performed so as to carry out erasure corrections for up to (d1−d) pieces of symbols at one time using the first inspection data. Therefore, an error correction method having a minimum number of times of decoding can be realized, and the error correction capability can be enhanced.

Further, in the above-described error correction method, when performing the second-time decoding using the position information Ex and Ey, erasure correction for up to n pieces of symbols and error correction for up to m pieces of errors whose error positions are unclear, which satisfy a relational formula of n+2m≦d1−1 (n, m: integers not less than 0), are performed at one time using the first inspection data. Therefore, error correction with higher precision can be realized.

Further, in the above-described error correction method, when performing the erasure correction using the position information Ex and Ey in the second-time decoding, it is selectable whether to use the position information Ey as an erasure position or not. Therefore, an optimum decoding method can be selected according to the data to be decoded.

Further, in the above-described error correction method, when performing the erasure correction using the position information Ex and Ey in the second-time decoding, the position information Ey is regarded as an erasure position if the number of the erasure symbols X is equal to or larger than a predetermined value, while the position information Ey is not regarded as an erasure position if the number of the erasure symbols X is less than the predetermined value. Therefore, the error correction method can be carried out with selecting, when the number of erasure symbols is large, an error correction method which can perform error correction with higher probability using the position information Ex and Ey based on a judgment that the recording state of the signal recorded on the disk is poor, and when the number of erasure symbols is small, an error correction method using only the position information Ex and having lesser erroneous correction.

### BRIEF DESCRIPTION OF THE DRAWINGS

FIG. 1 is a diagram for explaining a method for recording information on a compact disk, which information is doubly encoded by a Reed-Solomon code.

FIG. 2 is a diagram illustrating a flowchart of an error correction method according to a first embodiment of the present invention.

FIG. 3 is a diagram illustrating a flowchart of an error correction method according to a second embodiment of the present invention.

FIG. 4 is a diagram illustrating a flowchart of an error correction method according to a third embodiment of the present invention.

FIG. 5 is a diagram illustrating a flowchart of the conventional error correction method.

### DESCRIPTION OF REFERENCE NUMERALS

101 . . . information data
102 . . . first inspection data
103 . . . second inspection data
104 . . . C1 frame
105 . . . C2 frame

### BEST MODE TO EXECUTE THE INVENTION

Hereinafter, embodiments of the present invention will be described with reference to the drawings.

### Embodiment 1

Hereinafter, an error correction method according to a first embodiment of the present invention will be described.

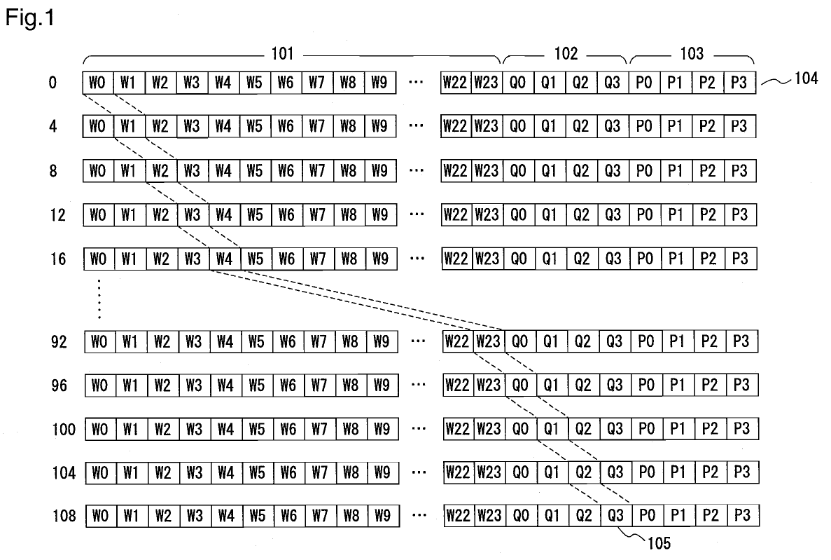

In the error correction method according to the first embodiment, as shown in FIG. 1, error detection and error correction are performed during performing decoding to a code word which is obtained by performing double encoding that comprises producing C2 frames 105 as first correction frames comprising plural pieces of information data 101 and first inspection data 102 having a minimum distance of d1 (d1: an integer not less than 2) and added to the plural pieces of information data 101, and producing a plurality of C1 frames 104 as second correction frames comprising a data sequence comprising symbols that are selected from the C2 frames 105 existing in a data assembly comprising a plurality of the C2 frames 105 and second inspection data 103 having a minimum distance of d2 (d2: an integer not less than 2) and added to the data sequence.

In this first embodiment, in C1 decoding, error detection and error correction for the C1 frames are performed using the second inspection data 103. According to the results of the error detection and error correction performed in the C1 decoding, a flag Ex is generated for each C1 frame 104 for which error detection was performed but error correction could not be performed, and a flag Ey is generated for each C1 frame 104 for which error detection was performed and error correction was performed.

Further, in C2 decoding, error detection and error correction are performed using the first inspection data 102 to the C2 frames 105 in the data assembly in which error detection and error correction were performed to the C1 frames 104 using the second inspection data 103. At this time, it is possible to perform erasure correction for up to (d1−1) pieces of symbols at one time by utilizing the position information Ex of erasure symbols X and the position information Ey of pseudo erasure symbols Y which are obtained in the C1 decoding.

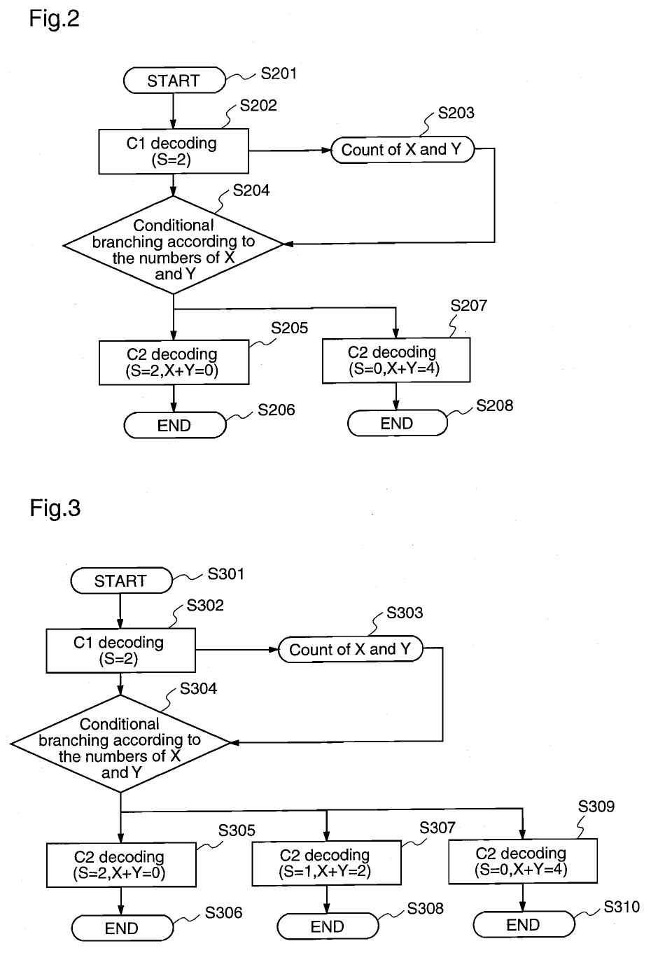

Hereinafter, the error correction method according to the first embodiment will be described with reference to FIG. 2. It is assumed that a Reed-Solomon code having a code length of 32, the number of inspection data being 4, and a minimum distance d1 from other data being 5 is used for the C1 decoding, while a Reed-Solomon code having a code length of 28, the number of inspection data being 4, and a minimum distance d2 from other data being 5 is used for the C2 decoding.

Decoding of data recorded on a compact disk is started (step S201), and initially, C1 decoding as first-time decoding is carried out (step S202).

Inspection data P0 to P3 of 4 symbols are added to information data W0 to W23 and Q0 to Q3 of 28 symbols in one frame which are target data of the C1 decoding so that a minimum distance from other frames becomes 5. Accordingly, in the C1 decoding, it is possible to perform error correction within a range that satisfies a relational formula of 2m+x≦4 (m is an integer not less than 0 which indicates the number of errors whose error positions are unclear, and x is an integer not less than 0 which indicates the number of erasure symbols X). In this C1 decoding, however, x is equal to 0 because there is no information relating to erasure symbols X, and it is possible to perform detection for up to four pieces of errors and error correction for up to two errors S whose error positions are unclear.

According to the results of the error detection and error correction performed in the C1 decoding, flags Ex are generated for symbols X for which error detection was performed but error correction could not be performed while flags Ey are generated for pseudo erasure symbols Y for which error detection was performed and error correction was performed, and the positions of the flags Ex and Ey are recorded as erasure positions. That is, all the symbols for which errors were detected but the errors could not be corrected in the C1 decoding are regarded as erasure symbols X and their position information Ex are recorded, and all the symbols for which two errors were detected and the two errors were corrected are regarded as pseudo erasure symbols Y and their position information Ey are recorded. In this first embodiment, only for a frame in which two errors were detected and the two errors were corrected, symbols for which the errors were detected and corrected in this frame are regarded as pseudo erasure symbols Y. However, also for a frame in which one error was detected and the error was corrected, a symbol for which the error was detected and corrected in this frame may be regarded as a pseudo erasure symbol.

Next, the C1 frame 104 after the C1 decoding is subjected to deinterleaving to rearrange the frame like the C2 frame 105 shown in FIG. 1, and then C2 decoding is carried out.

The inspection data Q0 to Q3 of 4 symbols are added to the data W0 to W23 of 24 symbols in one frame which are target data for the C2 decoding so that the minimum distance from other frames becomes 5. In order to perform decoding with these inspection data Q0 to Q3 being utilized more effectively, it is determined as to what kind of error correction should be performed in the C2 decoding, according to the number of erasure symbols X and the number of pseudo erasure symbols Y as follows.

Initially, the number of erasure symbols X and the number of pseudo erasure symbols Y in the frame are counted (step S203), and conditional branching is performed according to the counted numbers of erasure symbols X and pseudo erasure symbols Y (step S204).

For example, when the sum of the number of erasure symbols X and the number of pseudo erasure symbols Y is 0, error correction for up to two errors S whose error positions are unclear is performed (step S205), and the processing is ended (step S206).

When the sum of the number of erasure symbols X and the number of pseudo erasure symbols Y is 4 or less, erasure correction for up to (d1−1) pieces of symbols, i.e., four symbols, is performed at one time utilizing the position information Ex of the erasure symbols X and the position information Ey of the pseudo erasure symbols Y which are obtained in the C1 decoding (step S207), and the processing is ended (step S208).

When the sum of the number of erasure symbols X and the number of pseudo erasure symbols Y is 5 or more, error correction for up to two errors S whose error positions are unclear is performed with the number of erasure symbols X and the number of pseudo erasure symbols Y being ignored (step S205), and the processing is ended (step S206).

According to the error correction method of the first embodiment, for the code word which is doubly encoded such that the C2 frames 105 are formed by adding the first inspection data Q0 to Q3 to the information data W0 to W23 and the plural C1 frames 104 are formed by adding the second inspection data P0 to P3 to the data sequence of W0 to W23 and Q0 to Q3 comprising the symbols selected from the plural C2 frames, error detection and error correction are performed during the C1 decoding with using the second inspection data P0 to P3, and flags Ex are generated for the erasure symbols X for which error detection was performed but error correction could not be performed while flags Ey are generated for the pseudo erasure symbols Y for which error detection was performed and error correction was performed, according to the results of the error detection and error correction in the C1 decoding, and erasure corrections for up to (d1−1) pieces of symbols are carried out at one time using the positions of the flags Ex and Ey as erasure positions when performing the C2 decoding. Therefore, the processing efficiency can be enhanced by minimizing the number of times of error correction in the C2 decoding, and further, the error correction capability can be enhanced by the simple processing.

### Embodiment 2

Hereinafter, an error correction method according to a second embodiment of the present invention will be described.

The error correction method according to the second embodiment is characterized by that error correction for up to m pieces of errors S whose error positions are unclear and erasure correction for up to n pieces of symbols, which satisfy a relational formula of 2m+n≦d1−1 (m and n are integers not less than 0, and m indicates the number of errors S whose error positions are unclear while n indicates the sum of the number of erasure symbols X and the number of pseudo erasure symbols Y), are performed at one time during C2 decoding with using position information Ex of erasure symbols X and position information Ey of pseudo erasure symbols Y which are obtained in C1 decoding, in addition to the error correction method according to the first embodiment.

Hereinafter, the error correction method according to the second embodiment will be described with reference to FIG. 3. It is premised that a Reed-Solomon code having a code length of 32, the number of inspection data being 4, and a minimum distance d1 from other data being 5 is used for the C1 decoding, while a Reed-Solomon code having a code length of 28, the number of inspection data being 4, and a minimum distance d2 from other data being 5 is used for the C2 decoding.

Decoding of data recorded on a compact disk is started (step S301), and initially, C1 decoding as first-time decoding is carried out (step S302).

In the C1 decoding, detection for up to four errors and correction for up to two errors S whose error positions are unclear can be performed as in the first embodiment.

Then, according to the results of the error detection and error correction performed in the C1 decoding, flags Ex are generated for symbols X for which error detection was performed but error correction could not be performed and flags Ey are generated for pseudo erasure symbols Y for which error detection was performed and error correction was performed, and the positions of the flags Ex and Ey are recorded as erasure positions when performing C2 decoding.

Next, the C1 frame after the C1 decoding is subjected to deinterleaving to rearrange the frame like the C2 frame shown in FIG. 1, and then C2 decoding is performed.

In the C2 decoding, what kind of error correction should be performed is determined according to the number of erasure symbols X and the number of pseudo erasure symbols Y as follows.

Initially, the number of erasure symbols X and the number of pseudo erasure symbols Y in the frame are counted (step S303), and conditional branching is performed according to the counted numbers of erasure symbols X and pseudo erasure symbols Y (step S304).

For example, when the sum of the number of erasure symbols X and the number of pseudo erasure symbols Y is zero, error correction for up to two errors S whose error positions are unclear is performed (step S305), and the processing is ended (step S306).

When the sum of the number of erasure symbols X and the number of pseudo erasure symbols Y is two or less, error correction for up to one error S whose error position is unclear and erasure correction for up to two symbols are performed (step S307), and the processing is ended (step S308).

When the sum of the number of erasure symbols X and the number of pseudo erasure symbols is four or less, erasure correction for up to four symbols is performed (step S309), and the processing is ended (step S310).

When the sum of the number of erasure symbols X and the number of pseudo erasure symbols is five or more, error correction for up to two errors S whose error positions are unclear is performed with the number of erasure symbols X and the number of pseudo erasure symbols Y being ignored (step S305), and the processing is ended (step S306).

According to the error correction method of the second embodiment, erasure correction for up to n pieces of symbols and error correction for up to m pieces of errors S whose error positions are unclear, which satisfy a relational formula of n+2m≦d1−1 (m, n are integers not less than 0), are performed at one time during performing the C2 decoding with using the position information Ex of erasure symbols X and the position information Ey of pseudo erasure symbols Y which are obtained in the C1 decoding. Therefore, the number of times of error correction in the C2 decoding can be minimized and thereby the processing efficiency is enhanced, resulting in more precise error correction.

### Embodiment 3

Hereinafter, an error correction method according to a third embodiment of the present invention will be described.

The error correction method according to the third embodiment is characterized by that whether the position information Ey of a pseudo erasure symbol Y should be treated as an erasure position or not is determined in the C2 decoding, in addition to the error correction method of the second embodiment.

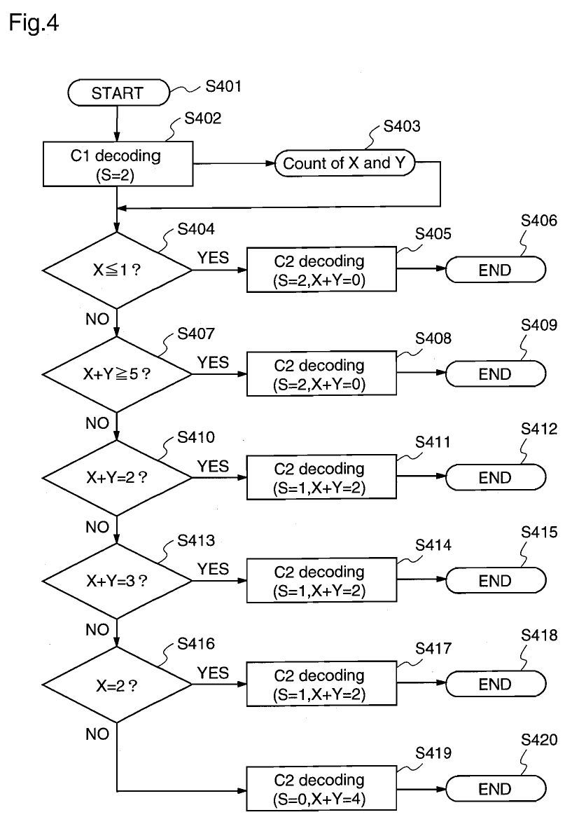

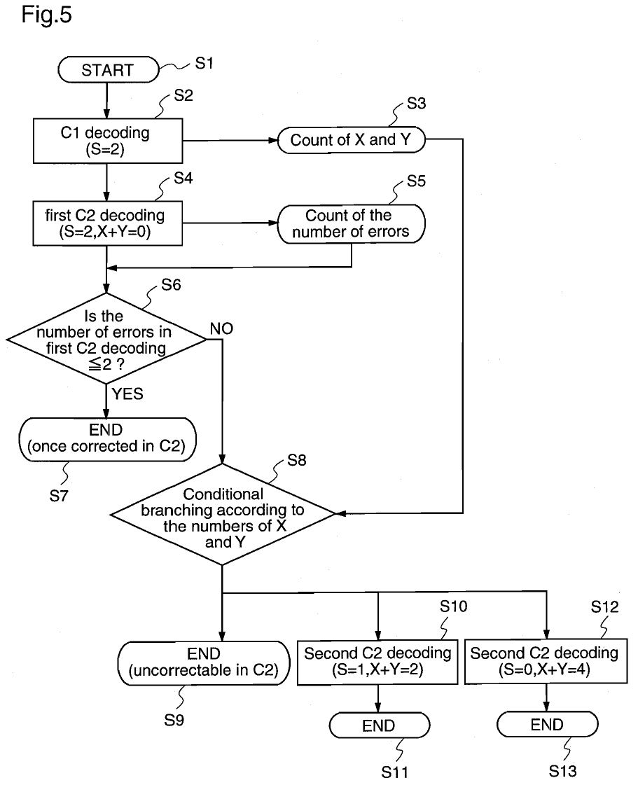

Hereinafter, the error correction method according to the third embodiment will be described with reference to FIG. 4. It is premised that a Reed-Solomon code having a code length of 32, the number of inspection data being 4, and a minimum distance d1 from other data being 5 is used for the C1 decoding, while a Reed-Solomon code having a code length of 28, the number of inspection data being 4, and a minimum distance d2 from other data being 5 is used for the C2 decoding.

Decoding of data recorded on a compact disk is started (step S401), and initially, C1 decoding as first-time decoding is carried out (step S402).

In the C1 decoding, detection for up to four errors and correction for up to two errors S whose error positions are not clear can be performed as in the first embodiment.

Then, flags Ex are generated for symbols X for which error detection was performed but error correction could not be performed, and flags Ey are generated for pseudo erasure symbols Y for which error detection was performed and error correction was performed, according to the results of the error detection and error correction performed in the C1 decoding, and the positions of the flags Ex and Ey are recorded as erasure positions when performing C2 decoding.

Next, the C1 frame obtained after the C1 decoding is subjected deinterleaving to rearrange the frame like the C2 frame shown in FIG. 1, and then C2 decoding is performed.

In the C2 decoding, what kind of error correction should be performed is determined according to the number of erasure symbols X and the number of pseudo erasure symbols Y as follows.

Initially, the number of erasure symbols X and the number of pseudo erasure symbols Y in the frame are counted, and conditional branching is performed according to the counted numbers (step S403).

### 1) Condition 1: X≦1?

It is judged whether or not the number of erasure symbols among the 28 symbols in the C2 frame is 0 or 1 (step S404).

When it is determined that the number of erasure symbols X is 0 or 1, error correction for up to two errors S whose positions are unclear is performed in C2 decoding (step S405), and the processing is ended (step S406).

When this condition is fulfilled, it indicates that the number of frames for which errors could not be corrected in the C1 decoding is small, and therefore, it is possible to decide that the number of symbols that need correction is small also in the C2 decoding.

### 2) Condition 2: X+Y≧5?

When it is determined in step S404 that the number of erasure symbols X is two or more, it is judged whether or not the sum of the number of erasure symbols X and the number of pseudo erasure symbols Y among the 28 symbols in the C2 frame is 5 or more (step S407).

When it is determined that the sum of the number of erasure symbols X and the number of pseudo erasure symbols Y is 5 or more, error correction for up to two errors S whose positions are unclear is performed in the C2 decoding (step S408), and the processing is ended (step S409).

When this condition is fulfilled, it indicates that the number of frames for which errors could not be corrected and frames for which errors were corrected in the C1 decoding are very large. Since the sum of the number of erasure symbols X and the number of pseudo erasure symbols Y is five or more in the C1 decoding, when erasure correction in the C2 decoding is executed for up to the maximum number, i.e., four symbols, if the remaining one or more X or Y symbols are errors, erroneous correction inevitably occurs in the corresponding frame.

Accordingly, in the C2 decoding under this condition, in order to avoid the occurrence of erroneous correction described above, erasure correction using the position information Ex and Ey is not performed, and the error detection capability is enhanced to suppress the probability of erroneous correction in the C2 decoding.

### 3) Condition 3: X+Y=2?

When it is determined in step S407 that the sum of the number of erasure symbols X and the number of pseudo erasure symbols Y is not 5 or more, it is judged whether the sum of the number of erasure symbols X and the number of pseudo erasure symbols Y among the 28 symbols in the C2 frame is 2 or not (step S410).

When it is determined that the sum of the number of erasure symbols X and the number of pseudo erasure symbols Y is 2, erasure correction for up to two symbols and error correction for up to one error S whose error position is unclear are performed in the C2 decoding (step S411), and the processing is ended (step S412).

When this condition is fulfilled, since the position information Ex or Ey of two erasure symbols X or pseudo erasure symbols Y are recorded in the C1 decoding, erasure correction for up to two symbols is performed using the two position information, and error correction for up to one error S whose error position is unclear can be performed.

### 4) Condition 4: X+Y=3?

When it is determined in step S410 that the sum of the number of erasure symbols X and the number of pseudo erasure symbols Y is not 2, it is judged whether the sum of the number of erasure symbols X and the number of pseudo erasure symbols Y among the 28 symbols in the C2 frame is 3 or not (step S413).

When it is determined that the sum of the number of erasure symbols X and the number of pseudo erasure symbols Y is 3, erasure correction for up to two symbols and error correction for up to one error S whose error position is unclear are performed in the C2 decoding (step S414), and the processing is ended (step S415).

When this condition is fulfilled, since the position information Ex or Ey of three erasure symbols X or pseudo erasure symbols Y are recorded in the C1 decoding, erasure correction for up to two symbols is performed using two of the three position information, and error correction for up to one error S whose error position is unclear can be performed.

When selecting two from the three position information, the position information Ex may be selected with priority to be used for the erasure correction. Even when the remaining one X or Y symbol which was not selected is not correct, this symbol can be corrected when performing error correction for up to one error S whose error position is unclear (however, if a symbol other than the X and Y symbols is not correct, erroneous correction undesirably occurs in the C2 decoding). When the remaining one X or Y symbol that was not selected is correct, error correction for up to one error can be performed for a symbol other than the X and Y symbols by performing error correction for up to one error S whose error position is unclear.

### 5) Condition 5: X=2?

When it is determined in step S413 that the sum of the number of erasure symbols X and the number of pseudo erasure symbols Y is not 3, it is judged whether the number of erasure symbols X among the 28 symbols in the C2 frame is 2 or not (step S416).

Since it is determined that the sum of the number of erasure symbols X and the number of pseudo erasure symbols Y is four when the processing enters this conditional branching, it is judged whether or not the number of erasure symbols X is two and the number of pseudo erasure symbols Y is two.

When it is determined that the number of erasure symbols X is two and the number of pseudo erasure symbols Y is two, erasure correction for up to two symbols and error correction for up to one error S whose error position is not clear are performed in the C2 decoding (step S417), and the processing is completed (step S418).

When this condition is fulfilled, since the position information Ex of two erasure symbols are recorded in the C1 decoding, erasure correction for up to two symbols is performed using the two position information Ex, and error correction for up to one error S whose error position is unclear is performed.

At this time, although the position information Ey of two pseudo erasure symbols Y have also been recorded in the C1 decoding, the position information Ey is ignored here. Thereby, even when the two symbols which were determined as erasure symbols X (which are highly likely to be errors) in the C1 decoding are errors, these symbols can be surely corrected.

Further, it is possible to reduce the probability of erroneous correction in the C2 decoding by performing error correction for up to one error S whose error position is unclear, with expecting that at least one symbol is a correct symbol between the two symbols which were regarded as the pseudo erasure symbols Y (which are more likely to be errors relative to other symbols but not so much as the erasure symbols X) in the C1 decoding.

That is, if the two symbols that were regarded as the pseudo erasure symbols Y in the C1 decoding are correct, error correction for up to one error S whose error position is unclear can be performed for symbols other than the X and Y symbols.

Since, under this condition, it is also effective to perform erasure correction for up to four symbols by utilizing the position information Ey of the two pseudo erasure symbols Y, either correction may be used according to the situation.

On the other hand, when it is determined in step S416 that the number of erasure symbols X among the 28 symbols in the C2 frame is not 2, i.e., when the number of erasure symbols X is four and the number of pseudo erasure symbols Y is zero or when the number of erasure symbols X is three and the number of pseudo erasure symbols Y is one, when it is determined that the number of erasure symbols X is four and the number of pseudo erasure symbols Y is zero or that the number of erasure symbols X is three and the number of pseudo erasure symbols Y is one, erasure correction for up to four symbols is performed in the C2 decoding (step S419), and the processing is ended (step S420).

When this condition is fulfilled, it is possible to correct many symbols (up to four symbols in each C2 frame) which could not be corrected in the C1 correction, by trying correction for only X and Y symbols with an expectation that all the symbols other than the four symbols which were regarded as erasure symbols X and pseudo erasure symbols Y in the C1 decoding are correct.

Also under this condition, it is effective to perform the C2 decoding by another decoding method. For example, under the condition that the number of erasure symbols X is three and the number of pseudo erasure symbols Y is 1, erasure correction for up to two symbols and error correction for up to one error S whose error position is unclear can be performed using only the position information Ex of two erasure symbols among the three erasure symbols. Therefore, either correction may be used according to the situation.

According to the error correction method of the third embodiment, it is selectable whether to use the position information Ey or not when performing erasure correction for up to n pieces of symbols and error correction for up to m pieces of errors S whose error positions are unclear, which satisfy a relational formula of n+2m≦d1−1 (n, m are integers not less than 0) at one time in the C2 decoding with using the position information Ex of erasure symbols X and the position information Ey of pseudo erasure symbols Y which are obtained in the C1 decoding. Therefore, an optimum decoding method can be selected according to the data to be decoded. For example, when decoding an audio disk, erroneous correction in the C2 decoding is avoided as much as possible by performing erasure correction using only the position information Ex of erasure symbols X. When decoding CD-ROM data, the number of frames which are uncorrectable in the C2 decoding is reduced as much as possible by performing erasure correction using both of the position information Ex and Ey of erasure symbols X and pseudo erasure symbols Y. In this way, an optimum C2 decoding method can be selected according to the situation.

Further, when performing erasure correction in the C2 decoding, the erasure correction is performed using both of the position information Ex and Ey of the erasure symbols X and the pseudo erasure symbols Y if the number x of the erasure symbols X is not less than a certain value z (z is an arbitrary integer not less than 0), while the erasure correction is performed using only the position information Ex of the erasure symbols X when the number x of the erasure symbols X is less than the value z. Therefore, a correction method having lesser erroneous correction in the C2 decoding can be selected. For example, when the number of the erasure symbols X is large, error correction can be executed with higher probability in the C2 decoding with using not only the position information Ex of the erasure symbols X but also the position information Ey of the pseudo erasure symbols Y based on a judgement that the recording state of the signal recorded on the disk is poor, and conversely, when the number of the erasure symbols X is small, error correction with lesser erroneous correction can be performed in the C2 decoding with using only the position information Ex of the erasure symbols X.

### APPLICABILITY IN INDUSTRY

An error correction method of the present invention can make best use of inspection data that were added during encoding, when performing decoding of a doubly encoded code word, and thereby the error correction capability is enhanced. Therefore, it is useful for decoding of information recorded on a compact disk or the like.

1. An error correction method for performing error detection and error correction to a code word during decoding, which code word is obtained by performing double encoding that comprises producing first correction frames each comprising plural pieces of information data and first inspection data having a minimum distance of d1 (d1: an integer not less than 2) and added to the plural pieces of information data, and producing plural second correction frames each comprising a data sequence comprising symbols that are selected from the respective first correction frames existing in a data assembly comprising said plural first correction frames and second inspection data having a minimum distance of d2 (d2: an integer not less than 2) and added to the data sequence, said method including:
a first error detection/correction step of performing error detection and correction for the second correction frames with using the second inspection data;
a flag generation step of generating a flag Ex for each of the second correction frames for which error detection was performed but error correction could not be performed, and generating a flag Ey for each of the second correction frames for which error detection was performed and error correction was performed, according to the results of the error detection and correction performed in the first error detection/correction step; and
a second error detection/correction step of performing erasure correction for up to n pieces of symbols and error correction for up to m pieces of errors whose error positions are unclear, which satisfy a relational formula of n+2m≦d1−1 (n, m: integers not less than 0), at one time with using the positions of the flags Ex and Ey as erasure positions, when performing error detection and correction using the first inspection data to the first correction frames included in the data assembly which are obtained by performing error detection and correction to the second correction frames with using the second inspection data.

2. (canceled)

3. An error correction method as defined in claim 1 wherein said second error detection/correction step includes selecting whether the position of the flag Ey is to be used as an erasure position or not.

4. An error correction method as defined in claim 3 wherein said second error detection/correction step includes performing erasure correction using the flags Ex and Ey when x≧z (z: an arbitrary integer not less than 0) while performing erasure correction using only the flags Ex when x<z, assuming that the number of the flags Ex in the first correction frames is x.
